(19) United States
(12) Patent Application Publication
(10) Pub. No.: US 2003/0154596 A1
(43) Pub. Date: Aug. 21, 2003

(54) Production line for one-sided and two-sided assembly of printed citcuits boards

(76) Inventors: Andreas Geitz, Puschendorf (DE); Uwe Kraps, Neunkirchen (DE)

Correspondence Address: HARNESS, DICKEY & PIERCE, P.L.C., P.O.BOX 8910, RESTON, VA, 20195, US

(21) Appl. No.: 10/275,545

(22) PCT Filed: May 9, 2001
(86) PCT No.: PCT/DE01/01759

(30) Foreign Application Priority Data
May 12, 2000 (DE) 100 23 358.9

(51) Int. Cl. B23P 19/00; H05K 3/34

(52) U.S. Cl. 29/742; 29/739; 29/840

(57) ABSTRACT

A production line (13) for the one-sided and two-sided assembly of printed circuit boards with components consists of two successive sections (13a, 13b), each comprising a printer (4), at least one printed circuit board assembly machine (6, 7, 8) and a vertical reflow soldering furnace (14), in the direction in which the printed circuit boards pass through. One of each of the assembly modules (6, 7, 8) that are necessary for the desired product flexibility and which are allocated to the processing of different components is provided in the production line (13), said modules being distributed between the two sections (13a, 13b), between which a reversing station (11) is located. The soldering furnace (14) of the second section (13b) is preferably followed by another reversing station (11) which can be switched on and off.

The invention relates to a production line for one-sided and two-sided assembly of printed circuit boards with components, the production line consisting of two successive sections, each comprising a printer, at least one assembly module and a soldering furnace, in the direction in which the printed circuit boards pass through.

In the simplest configuration, one section of such a production line comprises at least one printer, at least one assembly module for the automatic positioning of components on the printed circuit board passing through the line and a soldering furnace. Since the configuration of the assembly modules varies according to the components to be handled, because there are, for example, automatic assembly machines which handle only passive components, such as resistors, capacitors etc., while other automatic assembly machines are substantially used for positioning ICs with great accuracy, in the case of mixed assembly the production line must generally comprise two or more different assembly modules. If different assembly tasks are to be accomplished with the production line, according to choice, the production line must have all the assembly modules which are required for these tasks.

In this respect there are sometimes problems in the configuration of production lines with regard to the clock-controlled output of the individual assembly modules, if the following requirements are to be met:

production mix between subassemblies to be assembled with components on one side and subassemblies to be assembled with components on two sides, it being intended as far as possible for the two-sided assembly to be performed in a single pass

through the production line, i.e. without returning and passing through a second time,

product mix with very different assembly content, i.e. great range of variation of the ratio between active components and passive components.

So far, there are two known procedures for two-sided assembly:

In the case of the first method variant, the subassembly has components assembled on one side during a first pass through a single production line, whereupon the subassembly leaving the production line, assembled with components on one side, is transported back to the entry of the production line and then has components assembled on the other side during a second pass through the production line. A typical production line of this type with three different assembly modules and the customary reflow furnace in the form of a tunnel furnace in this case reaches a length of approximately 20 m.

In the case of the second variant, two identical production lines are connected one behind the other to form a combined production line, so that the return transport no longer occurs and the assembly with components on the other side takes place while the subassembly is passing through the second production line. For the production of a subassembly which has components assembled on one side, it is possible for only the first of the two identical production lines combined with each other to be used.

In the case of the known procedures, the production lines are optimized only for specific products, i.e. the flexibility of the production lines is low. In the case of the production lines arranged one behind other, each of these two production lines is equipped with the same assembly modules, i.e. the duplication of the production lines also doubles

the number of assembly modules and also doubles the overall length of the combined production line to approximately 40 m.

The invention is therefore based on the object of developing a novel production line which, along with high production and product flexibility, is at the same time suitable for one-sided and two-sided assembly of components in combined operation and in one pass, permits best possible clock-controlled output of the assembly modules and consequently a high output, in terms of overall length remains approximately within the limits of what is required in the case of the previously customary, individual production lines, and is particularly cost-effective in respect of construction expenditure.

This object is achieved by the invention as claimed in claim 1.

Because the two successive sections altogether have only the same number of assembly modules as are encountered in the case of the customary procedure described above in each individual section of the production line, the overall length of the production line consisting of two sections is reduced considerably. Equally, the cost expenditure is also reduced.

The production line according to the invention makes it possible to produce subassemblies with components assembled on one side and two sides in one pass, to provide any desired arrangements of the components on the two sides, provided only that the assembly modules present in the production line allow assembly with these components. More precise details are given in the description of the figures.

Advantageous developments of the invention are characterized in the subclaims.

The use of vertical reflow furnaces instead of the previously used tunnel furnaces in a preferred configuration of the invention likewise contributes to the noticeable shortening of the overall length. The special advantage of vertical reflow furnaces is reflected, however, in the increase in flexibility and is accounted for by the fact that they can be fully heated constantly during the operation of the production line and, nevertheless, the soldering effect can be selected according to requirements, depending on the product, because they solder only in the lower region. If a subassembly with components assembled only on the upper side is passed through the vertical reflow furnace, the soldering effect does not occur.

A particularly advantageous development, according to which the second soldering furnace is followed by a turning station, facilitates operation with two passes through the production line, to achieve the greatest possible product flexibility.

The invention is explained in more detail below on the basis of exemplary embodiments represented in the drawing.

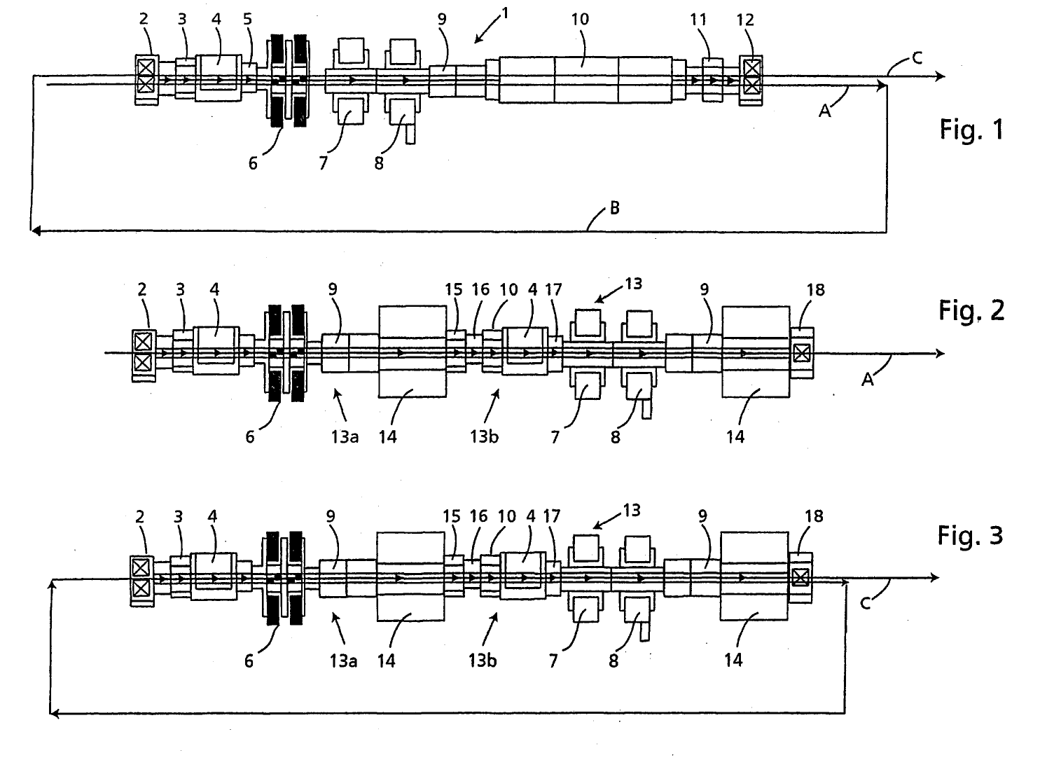

FIG. 1 represents a customary prior-art production line for comparison;

FIG. 2 shows a production line according to the invention with two successive sections, operation on the basis of a first assembly variant with one pass being represented; and

FIG. 3 shows the production line shown in FIG. 2 during operation based on a second assembly variant with two passes through the production line.

In the case of the production lines represented, the same standard modules are respectively used as automatic assembly machines, to be

precise the production lines are, for example, equipped with the Siemens products Siplace HS50, Siplace 80S23HM and Siplace 80F5HM, of which the Siplace HS50 assembly machine handles only passive components, such as resistors, capacitors, etc., while the Siplace 80F5HM assembly machine serves substantially for handling ICs with great accuracy (“fine pitch”).

The prior-art production line 1 shown in FIG. 1 begins with a magazine input 2, which is followed by a printed circuit board destacker 3. The individual printed circuit boards are passed through a printer 4, which prints conductor tracks onto a surface of the printed circuit board and is followed by an inspection belt 5. In a first assembly module 6 of the Siplace HS50 type, passive components are applied to the printed surface of the printed circuit board. The assembly is supplemented in a second assembly module 7 of the Siplace 80S23HM type and, finally, active components, such as ICs, which require great accuracy, can be applied to the printed circuit board in a third assembly module 8 of the Siplace 80F5HM type. The printed circuit board assembled with components according to requirements then passes through a reflow furnace 10 of a tunnel type of construction, which is adjoined by a turning station 11 and finally a magazine output 12. A printed circuit board to be assembled with components only on one side is passed on from here possibly to a station which is not shown for remaining assembly. The path of the printed circuit boards through the production line in one pass is represented by the material flow line A.

If the printed circuit board is to be assembled with components on two sides, the magazine with the turned printed circuit boards can be manually transported back to the entry of the production line, which is represented by the material flow line B, from where the turned printed circuit boards pass once again through the production line (material flow line C) and can then be assembled with components on the other side by the same working steps, so that

finally subassemblies assembled with components on both sides can be output into the magazine at the end of the production line and passed on for remaining assembly.

However, the turning station 11 may also be adjoined by a further production line 1, in which the assembly with components of the second side of the printed circuit board can then take place without the manual return transport of the magazine. In such a combined production line, if both sides of the printed circuit board are also to be assembled with “fine pitch” components, there may be two assembly modules 6, 7 and 8 in each, that is altogether six assembly modules.

The production line 13 according to the invention is represented in FIGS. 2 and 3, these production lines 13 in FIGS. 2 and 3 not differing in construction but only with regard to the way in which they are used.

The production line 13 is made up of two successive, different sections 13a and 13b.

The section 13a begins with a magazine input 2, which is followed by a printed circuit board destacker 3 and a printer 4. From there, the printed circuit boards pass to a first assembly module 6 of the Siplace HS50 type, from where they are passed on via a through-flow module 9 to a vertical reflow furnace 14. The printed circuit boards are transferred via a buffer 15, an inspection belt 16 and a turning station 11 to the second section 13b, where they firstly pass through a printer 4 and are then passed on via a belt or a spacer 17 to the second assembly module 7 of the Siplace 80S23HM type and the then following third assembly module 8 of the Siplace 80F5HM type. Via a further through-flow module 9, the printed circuit boards reach a second vertical reflow furnace 14, from which they are passed on to a magazine buffer 18.

In the case of the mode of operation represented in FIG. 2, the printed circuit boards are assembled with components in a single pass through the production line 13.

In the case of the production of a one-sided subassembly, the upper side of the printed circuit board is processed in the section 13a, i.e. the upper side of the printed circuit board is printed in the printer 4 and the upper side of the printed circuit board has components assembled on it in the first assembly module 6. If the printed circuit board then pass through the vertical reflow furnace 14 of the section 13a, no soldering takes place, since the subassemblies are taken past the process zones. In the turning station 11, the printed circuit board is not turned. The printer 4 of the second section 13b is likewise passed through without any action. Subsequently, the assembly with further components takes place in the assembly modules 7 and 8, before it reaches the vertical reflow furnace of the second section 13b, where the soldering of the printed circuit board takes place.

In the case of the double-sided assembly taking place in one pass, the printed circuit boards introduced into the section 13a are printed on the upper side in the printer 4 and assembled with components in the first assembly module 6, whereupon the soldering of this assembly takes place in the first vertical reflow furnace 14. In the turning station 11, the printed circuit board is turned over, the unassembled side, then facing upward, is printed in the printer 4 of the second section and assembled with components in the assembly modules 7 and 8, whereupon the soldering also takes place on this side in the vertical reflow furnace 14 of the second section 13b, whereupon the finished subassembly, assembled with components on two sides, leaves the production line 13.

If, for the sake of easier explanation, all the components which can be handled by the assembly module 6 are referred to as BE6, all the components which can be handled by the assembly module 7 are referred to as BE7 and all the components which can be handled by the assembly module 8 are referred to as BE8, it can be stated that, when a printed circuit board is assembled with components on one side

on the basis of the method described above with reference to FIG. 2, the surface can be assembled with components BE6, BE7 and BE8. In the case of assembly on two sides on the basis of the method described above, one surface may carry only components BE6 and the other surface components BE7 and BE8.

If the surface assembled with BE6 is also to receive components BE7 and/or BE8, or the surface assembled with BE7 and/or BE8 is also to receive components BE6, the production line 13 is passed through twice by the printed circuit board to be assembled, as is represented with reference to FIG. 3.

In this case, one side is assembled with components BE6, BE7 and/or BE8 in a first pass, with the method sequence corresponding to that which was described above for one-sided assembly, whereupon the printed circuit board is then turned and the other side is assembled with components in the same way in a second pass.

Expediently—if this operating mode is desired—a further turning station 11, which can be switched on and off according to choice is arranged at the end of the section 13b, in order that in this operating mode the printed circuit boards are inserted into the magazine in the position turned for the second pass before the return transport.

1. A production line (13) for one-sided and two-sided assembly of printed circuit boards with components, the production line (13) consisting of two successive sections (13a, 13b), each comprising a printer (4), at least one assembly module (6, 7, 8) and a soldering furnace (14), in the direction in which the printed circuit boards pass through, characterized in that one of each of the assembly modules (6, 7, 8) allocated to the handling of different components is provided in the production line (13) and said modules are distributed between the two sections (13a, 13b).

2. The production line as claimed in claim 1, characterized in that the soldering furnaces (14) are vertical reflow furnaces.

3. The production line as claimed in claims 1 and 2, characterized in that a turning station (11) is arranged between the two sections (13a, 13b).

4. The production line as claimed in as claimed in claim 3, characterized in that a turning station (11) is arranged downstream of the soldering furnace (14) of the second section (13b).

5. The production line as claimed in either of claims 3 and 4, characterized in that the turning station (11) arranged downstream of the soldering furnace (14) of the second section (13b) can be switched on and off according to choice.
